(19) United States
(12) Patent Application Publication
(10) Pub. No.: US 2024/0375541 A1
(43) Pub. Date: Nov. 14, 2024

(54) CONTACTOR DEVICE IDENTIFICATION

(71) Applicant: Volvo Truck Corporation, GÖTEBORG (SE)

(72) Inventors: Emil LIDSTRÖM, TORSLANDA (SE); Dripta RAY, Göteborg (SE)

(21) Appl. No.: 18/658,503

(22) Filed: May 8, 2024

(30) Foreign Application Priority Data
May 11, 2023 (EP) 23172887.4

(51) Int. Cl. B60L 58/10; H01H 47/00

(52) U.S. Cl. CPC B60L 58/10; H01H 47/001

(57) ABSTRACT

A computer system including processing circuitry configured to provide a control signal to a contactor device control circuit including a contactor, the contactor device control circuit being configured to carry out a state switch in response to receiving said control signal; receive a control signal response from the contactor device control circuit in response to said state switch; obtain one or more contactor device properties based on the control signal response to the control signal; compare the one or more contactor device properties to baseline contactor device properties, the baseline contactor device properties being indicative of one or more predefined contactor device types; and based on said comparison, identify whether a type of said contactor corresponds to said one or more predefined contactor device types.

### CROSS REFERENCE TO RELATED APPLICATION

This application claims foreign priority to European Application No. 23172887.4 filed on May 11, 2023, the disclosure and content of which is incorporated by reference herein in its entirety.

### TECHNICAL FIELD

The disclosure relates generally to contactor devices. In particular aspects, the disclosure relates to identification of contactor device types. The disclosure can be applied to heavy-duty vehicles, such as trucks, buses, and construction equipment, among other vehicle types. Although the disclosure may be described with respect to a particular vehicle, the disclosure is not restricted to any particular vehicle.

### BACKGROUND

Contactors device are arranged for switching control circuits on or off, and may be arranged in electrical devices. Such electrical devices include, for instance, charging systems, steering systems, motor systems, fuel systems, air conditioning systems, and other components. In the following disclosure, a contactor device is to be interpreted as an element capable of altering the flow of electricity in a circuit by a switching mechanism. To this end, a contactor device as used herein refers to contactors, switches or relays, etc.

The number of contactor devices are continuously increasing. Given the sheer amount of contactor devices arranged in today's devices, there is a significant risk of said contactor devices being tampered with once they are out on the aftermarket. For example, vehicle workshops and other third parties are seeing great potential in providing counterfeit vehicle contactor devices by replacing, changing and/or to some extent modifying the existing vehicle contactor devices for their own winnings. In the example of vehicles, counterfeiting of vehicle contactor devices can lead to devastating losses, as the vehicle may continue to operate under unsafe operating conditions, according to the vehicle manufacturer's safety and regulatory standards, without the driver necessarily knowing about it. Such losses involve safety hazards for the driver and anyone being in the vicinity of the vehicle. Moreover, the performance of various electrical devices may be degraded as said vehicle contactor devices are no longer recognizable. It is therefore desired to identify the type of contactor devices.

### SUMMARY

According to a first aspect of the disclosure, a computer system comprising processing circuitry is provided. The processing circuitry is configured to provide a control signal to a contactor device control circuit comprising a contactor. The contactor device control circuit is configured to carry out a state switch in response to receiving said control signal and to receive a control signal response from the contactor device control circuit in response to said state switch. The processing circuitry is further configured to obtain one or more contactor device properties based on the control signal response to the control signal and to compare the one or more contactor device properties to baseline contactor device properties. The baseline contactor device properties are indicative of one or more predefined contactor device types. The processing circuitry is further configured to, based on said comparison, identify whether a type of said contactor corresponds to said one or more predefined contactor device types. The first aspect of the disclosure may seek to identify the type of a vehicle contactor device. A technical benefit may include safe vehicle operating conditions and an increased performance of electrical devices of the vehicle since they may be able to correctly assess contactors of the vehicle as the type thereof may behave as expected of said type of contactor device.

Optionally in some examples, including in at least one preferred example, the processing circuitry is further configured to obtain the one or more contactor device properties by time series analysis on time series data included in the control signal response. A technical benefit may include a more accurate type identification . . .

Optionally in some examples, including in at least one preferred example, the processing circuitry is further configured to compare the one or more contactor device properties to the baseline contactor device properties by creating a response signature of the one or more contactor device properties based on the time series analysis; creating a baseline signature of baseline time series data included in the baseline contactor device properties; and comparing said response signature to the baseline signature. A technical benefit may include a more accurate type identification.

Optionally in some examples, including in at least one preferred example, the processing circuitry is further configured to create the baseline signature based on an output from a contactor device model being configured to process baseline contactor device properties of a plurality of said one or more predefined contactor device types. A technical benefit may include a more accurate type identification.

Optionally in some examples, including in at least one preferred example, the processing circuitry is further configured to compare the response signature to the baseline signature by identifying deviations exceeding a predefined threshold value. A technical benefit may include being able to adjust the hit rate of the comparison against a threshold value such that more adaptability can be achieved in the comparison.

Optionally in some examples, including in at least one preferred example, the processing circuitry is further configured to provide an identification report in response to said identification of whether a type of said contactor corresponds to one or more predefined contactor device types being performed. A technical benefit may include being able to compile the results of the type identification for further assessment thereof, for instance by a remote server at a workshop.

Optionally in some examples, including in at least one preferred example, the time series data pertain to a time-to-close duration of a closing operation of the contactor, said time-to-close duration being initiated upon said control signal being provided, said time-to-close duration ending upon completing the state switch, wherein the processing circuitry is further configured to determine the one or more contactor device properties as a function of a measured property of the control signal response in relation to a predefined property of the control signal during said closing operation. A technical benefit may include greater control and adaptability of how the identification is to be performed because the closing operation having the time-to-close duration is controllable and the input can accordingly be modelled in relation thereto.

Optionally in some examples, including in at least one preferred example, wherein the time series data pertain to a time-to-open duration of an opening operation of the contactor or a time-to-close duration of a closing operation of the contactor, said time-to-close or time-to-open duration being initiated upon said control signal being provided, said time-to-close or time-to-open duration ending upon completing the state switch, wherein the processing circuitry is further configured to control the opening operation or closing operation by pulse-width modulating the control signal. A technical benefit may include increasing the testing flexibility of various properties of the contactor device control circuit such that the identification procedure may become more accurate.

Optionally in some examples, including in at least one preferred example, the one or more contactor device properties are electrical properties and/or physical properties of the contactor. A technical benefit may include having a plurality of properties that can be compared to one another for increasing the identification accuracy.

Optionally in some examples, including in at least one preferred example, the time series data is obtained by one or more sensor units. A technical benefit may include being able to utilize existing sensors of the vehicle to identify the contactor device type which may involve a cheaper and less complex system.

Optionally in some examples, including in at least one preferred example, the contactor is a battery contactor. A technical benefit may include being able to identify specific battery contactor devices.

According to a second aspect of the disclosure, a vehicle comprising the computer system of the first aspect is provided. The second aspect of the disclosure may seek to identify the type of a vehicle contactor device. A technical benefit may include safe vehicle operating conditions and an increased performance of electrical devices of the vehicle since they may be able to correctly assess contactors of the vehicle as the type thereof may behave as expected of said type of contactor device.

According to a third aspect of the disclosure, a computer-implemented method for vehicle contactor device identification is provided. The method comprises providing, by processing circuitry of a computer system, a control signal to a contactor device control circuit comprising a contactor, the contactor device control circuit being configured to carry out a state switch in response to receiving said control signal; receiving, by the processing circuitry, a control signal response from the contactor device control circuit in response to said state switch being carried out; obtaining, by the processing circuitry, one or more contactor device properties based on the control signal response to the control signal; comparing, by the processing circuitry, the one or more contactor device properties to baseline contactor device properties, the baseline contactor device properties being indicative of one or more predefined contactor device types; and based on said comparison, identifying, by the processing circuitry, whether a type of said contactor corresponds to said one or more predefined contactor device types. The third aspect of the disclosure may seek to identify the type of a vehicle contactor device. A technical benefit may include safe vehicle operating conditions and an increased performance of electrical devices of the vehicle since they may be able to correctly assess contactors of the vehicle as the type thereof may behave as expected of said type of contactor device.

According to a fourth aspect of the disclosure, a computer program product is provided. The computer program product comprises program code for performing, when executed by the processing circuitry, the method of the third aspect. The fourth aspect of the disclosure may seek to identify the type of a vehicle contactor device. A technical benefit may include safe vehicle operating conditions and an increased performance of electrical devices of the vehicle since they may be able to correctly assess contactors of the vehicle as the type thereof may behave as expected of said type of contactor device.

According to a fifth aspect of the disclosure, a non-transitory computer-readable storage medium is provided. The non-transitory computer-readable storage medium comprises program code for performing, when executed by the processing circuitry, the method of the third aspect. The fifth aspect of the disclosure may seek to identify the type of a vehicle contactor device. A technical benefit may include safe vehicle operating conditions and an increased performance of electrical devices of the vehicle since they may be able to correctly assess contactors of the vehicle as the type thereof may behave as expected of said type of contactor device.

The disclosed aspects, examples (including any preferred examples), and/or accompanying claims may be suitably combined with each other as would be apparent to anyone of ordinary skill in the art. Additional features and advantages are disclosed in the following description, claims, and drawings, and in part will be readily apparent therefrom to those skilled in the art or recognized by practicing the disclosure as described herein.

There are also disclosed herein computer systems, control units, code modules, computer-implemented methods, computer readable media, and computer program products associated with the above discussed technical benefits.

### BRIEF DESCRIPTION OF THE DRAWINGS

Examples are described in more detail below with reference to the appended drawings.

FIG. 1 is an exemplary system diagram of a heavy-duty vehicle according to one example.

FIG. 2 is an exemplary schematic block diagram visualizing data being used by the heavy-duty vehicle for vehicle contactor type identification according to one example.

FIG. 3 is an exemplary schematic block diagram visualizing exemplary contactor device properties.

FIG. 4 is an exemplary schematic block diagram visualizing vehicle contactor type identification based on signatures according to one example.

FIG. 5 is an exemplary illustration visualizing signature deviations according to one example.

FIGS. 6A-B illustrate an exemplary contactor device model and exemplary data used by said contactor device model according to one example.

FIG. 7 is an exemplary schematic flowchart illustration of a method according to one example.

FIG. 8 is a schematic diagram of a computer system for implementing examples disclosed herein according to one example.

### DETAILED DESCRIPTION

The detailed description set forth below provides information and examples of the disclosed technology with sufficient detail to enable those skilled in the art to practice the disclosure.

As indicated in the above Background section, in prior art vehicles there are significant risks of contactor devices being tampered with once the vehicles are out on the aftermarket. The present disclosure provides an insightful approach of identifying a type of the contactor device by obtaining one or more contactor device properties and comparing them to baseline contactor device properties being indicative one or more predefined contactor device types. The disclosed approach is also applicable for contactor device type identification in general, and not only for counterfeit detection. Other reasonable areas of application may be for maintenance of the vehicle (parts) or general analysis of contactor device types in vehicles. Various deviations exhibited in the data of the contactor device properties can be compared to the baseline contactor device properties, the baseline contactor device properties serving as reference to how the contactor device control circuit outputting a control signal response from which the contactor device properties were obtained is expected to be behaving. By identifying anomalies, it can, for example, be established what type of contactor device the contactor comprised in the contactor device control circuit is associated with. By knowing what type said contactor device is associated with, it can be assessed if there are potential counterfeit contactor devices being arranged in the vehicle during its time on the aftermarket. To this end, safe operating conditions can be assured according to the vehicle manufacturer's safety and regulatory standards. In addition, the performance of various electrical devices of the vehicle will be reliable since they may be able to correctly assess the recognizable vehicle contactor devices.

The present disclosure generally describes vehicle contactors. In this regard and in all other contexts of the present disclosure where the term “contactor” is used, the skilled person will appreciate that it should not necessarily be limited to a contactor of a vehicle. Rather, in the present context, a contactor may alternatively be arranged in other energy storage systems that use contactors, including but not limited to industrial machines, electric motors, lighting systems, heating systems, capacitor banks, thermal evaporator, electrical loads, and much more. Moreover, it should be understood that the term “contactor device” as used in the present disclosure refers to a “contactor”, which is comprised in a “contactor device control circuit”.

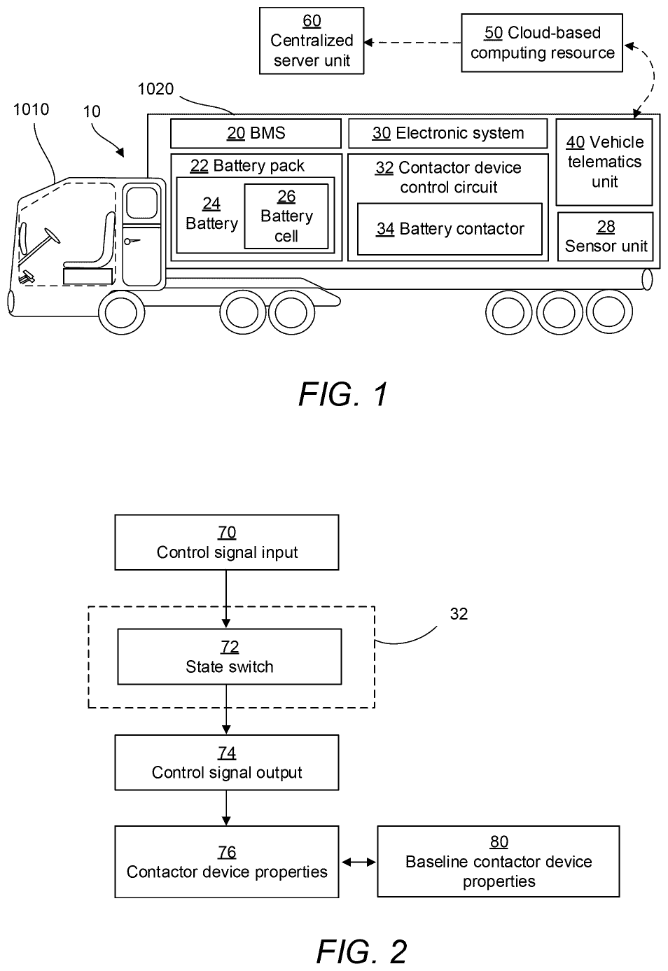

FIG. 1 is an exemplary schematic illustration of a heavy-duty vehicle 10 (hereinafter referred to vehicle 10 for reasons of brevity). This particular vehicle 10 comprises a tractor unit 1010 which is arranged to tow a trailer unit 1020. In other examples, other heavy-duty vehicles may be employed, e.g., trucks, buses, and construction equipment. Although not explicitly visualized in the figure, the skilled person will appreciate that the vehicle 10 comprises all necessary vehicle units and associated functionality such that it may operate as the skilled person would expect of a vehicle 10. Emphasis in the present disclosure is instead directed at contactor device identification, as will now be discussed.

The vehicle 10 comprises a battery management system (BMS) 20. The BMS 20 is configured to carry out a wide range of functionalities associated with at least one battery pack 22 of the vehicle 10. Such wide range of functionalities may vary depending on the type of vehicle 10 and its operating conditions, but generally includes one or more of battery monitoring, battery protection, battery operational state estimation, battery performance optimization and battery operation status reporting. These actions are carried out with respect to the battery pack 22.

The battery pack 22 is arranged in the vehicle 10 and adapted to power electrical devices (not shown) of the vehicle 10, such as charging systems, steering systems, motor systems, fuel systems, air conditioning systems, and other vehicle components. Each battery pack 22 comprises at least one battery 24. Each battery 24 comprises one or more battery cells 26. Each battery cell 26 comprises a single anode and cathode separated by electrolyte that is used to provide a voltage and current. The BMS 20 may be configured to monitor the one or more battery cells 26. Different types of batteries 24 comprise various numbers of battery cells 26. Moreover, the battery cells 26 may be of different types for different types of batteries 24. By way of example, a lithium-ion battery may comprise three cells to provide an 11.1 V battery, four cells to provide a 14.8 V battery, or 10 cells to provide a 37 V battery. Hence, the number and/or type of battery cells 26 may determine the amount of voltage and current being produced, which is consequently being monitored by the BMS 20. In some examples, other types of battery cells 26 making up other batteries 24 may be realized, such as lead-acid batteries or nickel-metal hydride batteries. The functionalities explained above associated with the BMS 20 may be applied to either the entirety of the at least one battery pack 22, portions thereof (e.g., one or more individual batteries 24), or even individual battery cells 26. The present disclosure is not limited to any number or types of battery packs 22, batteries 24 or battery cells 26.

The vehicle 10 comprises a contactor device control circuit 32. As described in the Background section, the contactor device control circuit 32 may be a circuit of a contactor, relay or switch and being arranged in any of the electrical devices as discussed above, for instance in the battery pack 22 or batteries 24 thereof. The contactor device control circuit 32 comprises a contactor 34. The contactor 34 is a switching element capable of adjusting the control signals transferred through said contactor device control circuit 32. In this example, the contactor 34 is a battery contactor 34, although it should be understood that any other type of contactors may be realized with respect to the present disclosure. The battery contactor 34 may be a high-voltage contactor or high-voltage relay. The battery contactor 34 is configured to carry out state switches in response to signals flowing through the contactor device control circuit 32. Although not shown in FIG. 1, the contactor device control circuit 32 may include other components as well, such as fuses, circuit breakers and sensors configured to ensure a safe operation of the contactor device control circuit 32. The battery contactor 34 may be an electromechanical switch configured to respectively engage and disengage a metal plate, such as a copper plate, to and from the leads of a high-voltage current path of the contactor device control circuit 32, thereby mechanically operating an electric contact. The electromechanical switch may comprise a solenoid, i.e., a cylindrical coil of wire, and a plunger rod. The plunger rod is made of a material inherently capable of resisting permanent magnetization, such as copper or aluminum. Electrical signals passing through the solenoid creates a magnetic field that attracts the plunger rod. The metal plate is attached to the plunger such that the engagement/disengagement of the plate to and from the current path of the contactor device control circuit 32 is enabled. The electromechanical switch may be a relay.

A contactor device control circuit 32 may be connected to battery cells 26. The battery cells 26 may be a stack of battery cells 26. The stack of battery cells 26 corresponds to a series of individual battery cells 26 being stacked together to create a higher voltage throughput (e.g., two 12 V batteries stacked together may output 24 V). The battery contactor 34 of the contactor device control circuit 32 may be respectively engaged and disengaged to and from the stack of battery cells 26. The battery contactor 34 may thus be configured to connect or disconnect the entire stack of battery cells 26 to or from an electrical machine.

The vehicle 10 comprises an electronic system 30. The electronic system 30 may be embedded in one or more of the battery packs 22 or associated batteries 24. Alternatively, the electronic system 30 may be partly embedded in the one or more battery packs 22 or associated batteries, and partly comprised in a cloud-based computing resource 50. Yet alternatively, the electronic system may be entirely comprised in the cloud-based computing system 50, with associated interfaces to collect data from and provide data to the contactor device control circuit 32. The electronic system 30 comprises processing circuitry being configured to control contactors of the vehicle 10, i.e., one or more contactor device control circuits 32 having respective battery contactors 34. The electronic system 30 is configured to provide one or more control signals to the contactor device control circuit 32 for controlling the contactor device control circuit 32 to carry out a state switch. To this end, the control signal may be a CLOSE or OPEN signal (0 or 1), indicating that the contactor device control circuit 32 is to carry out a closing operation or an opening operation. Once the state switch is carried out, the contactor device control circuit 32 generates a control signal response which is received by the processing circuitry of the electronic system 30. Since one particular contactor device control circuit 32 may be different from another one with respect to various electrical or physical properties, the control signal response exhibits different behaviors. In order to establish the different behaviors, one or more sensor units 28 may be utilized.

The vehicle 10 advantageously comprises at least one sensor unit 28. The sensor unit 28 is arranged to provide measurements of the contactor device control circuit 32. A single sensor unit 28 may be configured to provide measurements from one or more contactor device control circuits 32. Alternatively, one sensor unit 28 may be arranged and configured in operation with a respective contactor device control circuit 32. To this end, the vehicle 10 may comprise a plurality of sensor units 28, each sensor unit 28 being arranged at a respective contactor device control circuit 32.

The sensor unit 28 may be any type of sensor capable of measuring data associated with the control signal response. The sensor unit 28 may be of different sensor types, including but not limited to voltage sensors, current sensors, temperature sensors, electrochemical sensors, State of Charge (SoC) sensors, State of Health (SoH) sensors, gas sensors, pressure sensors, humidity sensors, accelerometers, optical sensors, magnetic sensors, or ultrasonic sensors. The sensor unit 28 may be configured as a combination of one or more of these various sensor types. Different sensor units 28 may be realized as one or more of these mentioned sensor types.

The processing circuitry of the electronic system 30 is configured to obtain one or more contactor device properties based on the control signal response to the control signal. “Based on” shall in this context be interpreted as the properties being obtained from the control signal response (output) to a corresponding control signal (input). This may be done by analyzing the data measured by the sensor unit(s) 28. The processing circuitry is configured to compare the contactor device properties to baseline contactor device properties which are indicative of one or more predefined contactor device types. Once the comparison has been carried out, the processing circuitry is configured to identify whether a type of the contactor device control circuit 32 matches or to some extent corresponds to one particular type from among the one or more predefined contactor device types. Accordingly, the processing circuitry may carry out vehicle contactor device identification.

A “contactor device type” is to be broadly interpreted according to various considerations and factors. For example, one or more of the following contactor device types are typically arranged in vehicles: high-voltage DC contactors, main contactors, pre-charge contactors, service disconnect contactors, inverter contactors, power contactors, DC-DC converter contactor, auxiliary power contactors, BMS contactors, charging port contactors, brake control contactors, HVAC contactors, power steering contactors, electric water pump contactors, electric oil pump contactors, fuel pump contactors, starter contactors, ignition coil contactors, headlight contactors, windshield wiper contactors and horn contactors. The skilled person realizes other types of contactors readily found in vehicles and associated electrical machines. Moreover, even a minor difference in one or more physical and/or electrical properties of a first contactor device type can distinguish it from a second contactor device type, even if they are of the same type. Such minor difference may be related to preferences different manufacturers put on their contactor device type, e.g., dimensions, sizes, signal outputs, and so forth, but may also pertain to the functionality of the contactor device control circuit. By way of example, a first BMS contactor manufactured by an original equipment manufacturer (OEM) can, on the face of it, appear similar to a second BMS contactor that has been manufactured by a third party not being said OEM. To this end, the minor difference(s) exhibited by the physical and/or electrical properties of the BMS contactors may be identified thanks to the concepts defined by the present disclosure relating to vehicle contactor device identification.

The vehicle 10 advantageously comprises a vehicle telematics unit 40. The vehicle telematics unit 40 is configured for obtaining data from the vehicle 10, such as from the electronic system 30 or the BMS 20, and communicate said data wirelessly to an external service. The identification results may be transmitted by the vehicle telematics unit 40 to a cloud-based computing resource 50 during an ongoing operation of the vehicle 10, i.e., in online mode. Alternatively, or additionally, control signal responses may be sent as raw data to the cloud-based computing resource 50, and subsequent obtaining, comparing and identifying of the type of contactor may be performed by the cloud-based computing resource 50. To this end, the contactor type identification may be carried out remote from the vehicle 10. In some examples, the cloud-based computing resource 50 may receive control signal responses from a vehicle fleet comprising a plurality of vehicles and carry out the identification procedure based on information received from said vehicle fleet. The identification results may be transmitted as an identification report in response to the identification of whether a type of said contactor device control unit 32 corresponds to a type of the one or more predefined contactor device types being performed. The operation of the vehicle 10 may be a particular usage of the vehicle 10, such as a start-up at a first location, a drive to a second location, and a shutdown at said second location. Such online data transmission may be realized in at least near real-time, where at least near real-time is to be interpreted as involving some minor delay caused by, for instance, network connectivity, latencies, or other similar reasons. In some examples, batch processing and transfer of the data may be realized. In this particular example, the vehicle telematics unit 40 is configured to be in communication with a cloud-based computing resource 50. The communication may be based on any known short-range or long-range standards or protocols known in the art. The following list of examples are some exemplary network/radio communication standards or protocols that may be employed by the vehicle telematics unit 40 and the cloud-based computing resource 50: HTTP(S), TCP/IP, UDP, FTP, SMTP, DNS, DHCP, SSH, POP3, SCP, NFS, SFTP, ICMP, ARP, RTP, RTCP IEEE 802.11, IEEE 802.15, ZigBee, WirelessHART, WiFi, Bluetooth®, BLE, RFID, WLAN, MQTT IoT, CoAP, DDS, NFC, AMQP, LoRaWAN, Z-Wave, Sigfox, Thread, EnOcean, mesh communication, any form of proximity-based device-to-device radio communication, LTE Direct, W-CDMA/HSPA, GSM, UTRAN, LTE, IPv4, IPv6, 6LoWPAN, IrDA, or 5G NR.

The cloud-based computing resource 50 may be implemented using any commonly known cloud-computing platform technologies, such as e.g. Amazon Web Services, Google Cloud Platform, Microsoft Azure, DigitalOcean, Oracle Cloud Infrastructure, IBM Bluemix or Alibaba Cloud. The cloud-based computing resource 50 may be included in a distributed cloud network that is widely and publically available, or alternatively limited to an enterprise. The cloud-based computing resource 50 may comprise a cloud-based storage unit. The cloud-based storage unit may be included with or external to the cloud-based computing resource 50. Connection to the cloud-based storage unit may be established using DBaaS (Database-as-a-service). For instance, the cloud-based storage unit may be deployed as a SQL data model such as MySQL, PostgreSQL or Oracle RDBMS. Alternatively, deployments based on NoSQL data models such as MongoDB, Amazon DynamoDB, Hadoop or Apache Cassandra may be used. DBaaS technologies are typically included as a service in the associated cloud-based computing resource 50.

The cloud-based computing resource 50 may be in further communication with a centralized server unit 60. Communication between the cloud-based computing resource 50 and the centralized server unit 60 may be realized by any of the communication standards or protocols as mentioned above with respect to the cloud-based computing resource 50 and the vehicle telematics unit 40. The centralized server unit 60 may be configured for collecting and analyzing data from a plurality of vehicles, and subsequently provide new and/or updated data to said plurality of vehicles based on various factors such as new contactor device types or characteristics.

In some examples, the identification results are not necessarily transferred from the vehicle telematics unit 40 to the centralized server unit 60 during an ongoing operation of the vehicle 10. Instead, the identification results may be transferred in an offline fashion after the vehicle 10 has finished an operation. Hence, the vehicle telematics unit 40 is configured to store the identification results during the operation, but the transfer is not effected until after said operation is completed. This may be realized in certain situations, such as at vehicle workshops or other vehicle maintenance locations.

FIG. 2 is an exemplary schematic block diagram visualizing data being used by the vehicle 10 for contactor device identification. The data flow is initiated by the provision of a control signal 70 to a contactor device control circuit 32. In response to receiving the control signal 70, the contactor device control circuit 32 is configured to carry out a state switch 72. Once the state switch 72 is carried out, the contactor device control circuit 32 accordingly generates a control signal response 74, and or more contactor device properties 76 are obtained based on the control signal response 74 to the control signal.

The state switch 72 may be a closing operation of the contactor 34. The closing operation pertain to a time-to-close duration which is initiated upon the control signal 70 being provided, and ends upon the closing operation state switch 72 being completed, for instance as achieved upon the metal plate disengaging the high-voltage current path of the contactor device control circuit 32. Where the state switch 72 is a closing operation, the contactor device properties 76 may be determined as a function of a measured property, such as current or voltage, of the control signal response 74 in relation to a predefined property, such as current or voltage, of the control signal 70. A time-curve may accordingly be generated of said function, which depend on physical and/or electrical properties of the contactor 34, such as dimensions of internal parts thereof (e.g., solenoid, plunger rod, fuse, breaker, and so forth). For example, during the closing operation, the voltage and/or current of the contactor device control circuit 32 controlling the solenoid will, as a function of time, have a shape that depends on the movement of the plunger and the time it takes for the plunger to complete the movement. Two different contactors having different plungers or solenoid are therefore expected to exhibit different behaviors of voltage and/or current as respective functions of time.

In alternative examples, the state switch 72 may be either one of a closing operation or an opening operation. Similar to the closing operation, the opening operation pertain to a time-to-open duration that is realized the same way, i.e., the time between the provisioning of the control signal 70 until the opening operation state switch 72 being completed. For said alternative examples where the state switch 72 is either one of a closing operation or an opening operation, the control signal 70 may be controlled by pulse width modulation (PWM). By adjusting the width of the pulses of the control signal 70, the average voltage or current provided by the control signal response 74 can be controlled. This may increase the testing flexibility of various properties of the contactor device control circuit 32 such that the identification procedure may become more accurate. Pulse frequency modulation (PFM) is another method that may be realized for state switches 72 being either one of a closing operation or an opening operation. Finally, the obtained contactor device properties 76 are compared to baseline contactor device properties 80.

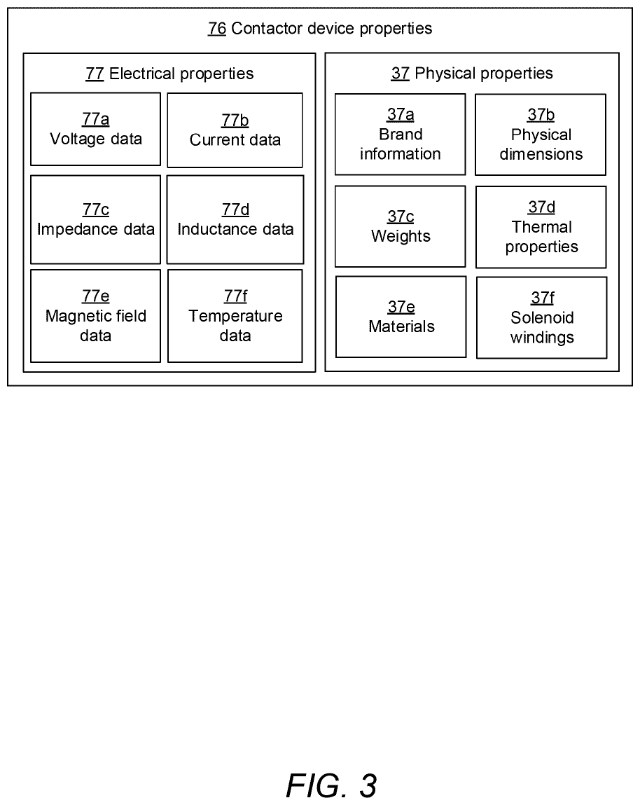

FIG. 3 shows exemplary contactor device properties 76. As discussed above, the processing circuitry of the electronic system 30 may be configured to obtain one or more contactor device properties 76 including electrical properties 77 and/or physical properties 37 of contactors. The electrical properties 77 and the physical properties 37 may be related to one another. For example, variations in voltage or current in the contactor device control circuit affects the physical components such as the solenoid and the metal plate associated therewith. The properties 37, 77 shown in FIG. 3 may include any additional or fewer properties than those shown. The electrical properties 77 include voltage data 77a, current data 77b, impedance data 77c, inductance data 77d, and magnetic field data 77e. The physical properties 37 include brand information 37a, physical dimensions 37b and weights 37c of components of the contactor device, thermal properties 37d, materials 37e and solenoid windings 37f. Some of the properties, such as the voltage data 77a and the current data 77b, may be obtained directly by measuring the voltage and current of the control signal response, for instance by the sensor units as discussed above. Other properties, such as the physical dimensions 37b of internal components of the contactor device may, for example, be obtained from an appearance of the resulting voltage over time function in relation to the provided control signal 70.

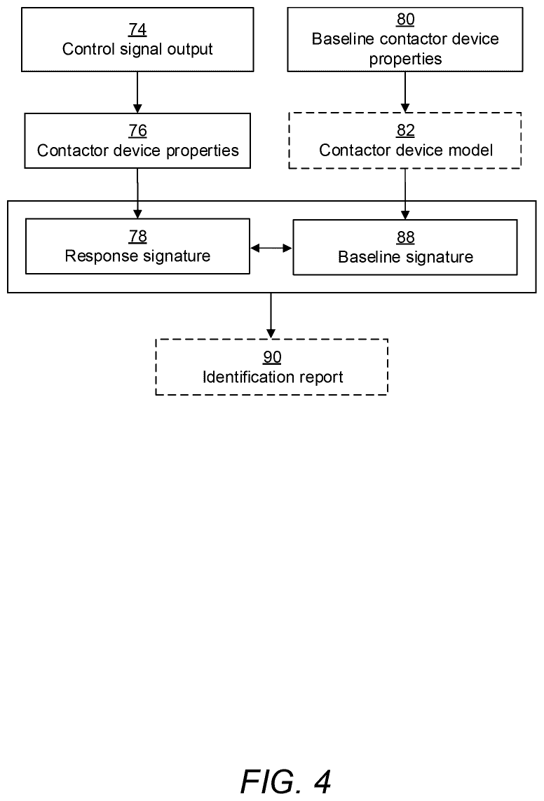

One or more of the contactor device properties 76 may indicate variations in contactor device types that can be identified by comparing said contactor device properties 76 to corresponding baseline contactor device properties 80. One such exemplary comparison approach will now be explained with reference to FIG. 4.

In FIG. 4, one example of providing an identification report 90 of vehicle contactor device identification results is shown. The identification is based on time series analysis. More specifically, one or more contactor device properties 76 are obtained by time series analysis on time series data included in the control signal response 74. Since the control signal response 74 pertain to various durations of closing and/or opening operations of state switches of the contactor, these durations are in this example being analyzed using time series analysis.

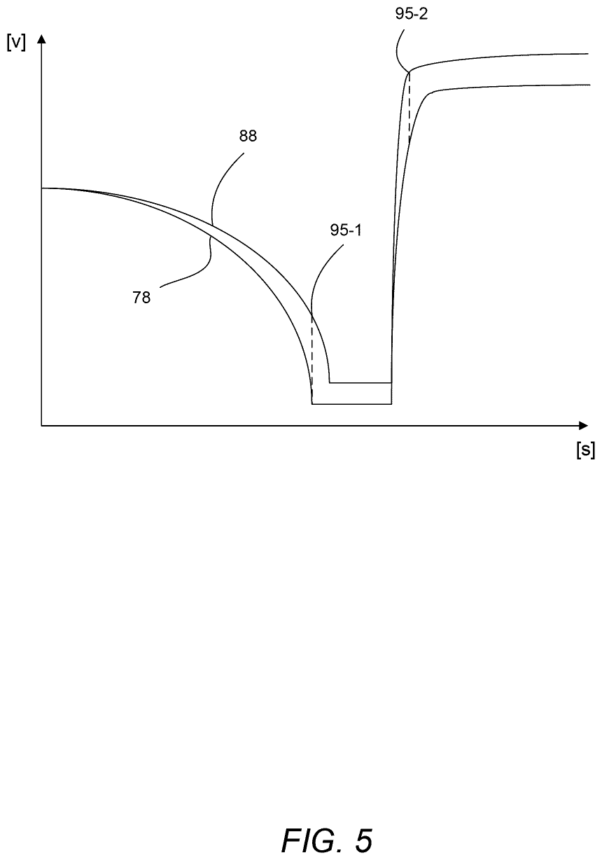

The comparison between the contactor device properties 76 and the baseline contactor device properties 80 may be carried out with respect to corresponding signatures thereof, said signatures being created based on respective time series data. The term “signature” can alternatively be interpreted as a fingerprint, identifier, or other such terms that define various characteristics of properties over time. A response signature 78 is created of the one or more contactor device properties 76 based on the time series analysis. Moreover, a baseline signature 88 of baseline time series data included in the baseline contactor device properties 80 is created. The baseline signature 88 thus serves as a reference to how the contactor device control circuit outputting the control signal response 74 from which the contactor device properties 76 are obtained is expected to be behaving. By identifying anomalies, it can be established what type of contactor device the contactor of the contactor device control circuit is associated with. The respective signatures 78, 88 are then compared to one another for providing the identification results in the form of the identification report 90. The features of the signatures 78, 88 depend on what properties 76, 80 they are based upon. To this end, if the signatures 78, 88 are created as a function of voltage over time of a closing or opening state switch, the respective voltage functions are compared to one another over time. This is shown according to one example in FIG. 5.

FIG. 5 shows an exemplary approach of comparing the response signature 78 to the baseline signature 88. In this particular example, the signatures 78, 88 are respectively created by analyzing voltage [v] time series data over time [t], although alternative variations are clearly possible. As indicated in the illustration, the signatures 78, 88 differ slightly. However, at two particular points in time, 95-1 and 95-2, signatures 78, 88 differ to an extent such that the deviations exceed a predefined threshold value (not shown in FIG. 5). This may be an indication that the control signal response 74 outputted by the contactor device control circuit 32 does not correlate to an expected control signal response as determined by the baseline signature 88 serving as a reference behavior of the expected response signature 78. The deviations indicated by the times 95-1, 95-2 may thus indicate that the type of the contactor does not correlate to the baseline type thereof. This may by extension indicate that the contactor has been tampered with (e.g., replaced or modified) during the vehicle's time at the aftermarket.

With further reference to FIG. 4, the identification report 90 may in some examples be based on a plurality of determined and compared signatures. Adding further conditions to determine a deviation may increase the accuracy of the identification procedure. By way of example, the voltage time series analysis as depicted in FIG. 5 may be complemented with a corresponding impedance data time series analysis, and potential deviations may require both of the analyses to respectively exceed a predefined threshold value in order to establish a potential deviating type. Alternatively, one of the time series analyses may be associated with a predefined threshold value that differ from the predefined threshold value of the other time series analysis depending on operating conditions. Any such additional and/or alternative considerations may be taken into account depending on the circumstances surrounding the identification of the type of the contactor.

The baseline signature 88 may be created by the approach as discussed above, namely based on baseline time series data of said one or more predefined contactor device types. This approach may be suitable when it is desired to directly compare the response signature 78 to a (known) selected type of baseline signature 88 where a match is expected. This may be the case where it is desired to confirm whether a particular contactor is the same type that was originally arranged in the vehicle.

Another approach is based on employing a contactor device model 82. Using this approach, the baseline signature 88 is instead based on an output from the contactor device model 82 being configured to process baseline contactor device properties 80 of a plurality of said one or more predefined contactor device types. Hence, this approach may be suitable when it is desired to find out what type, from among a plurality of baseline contactor device types, the contactor corresponds to.

The contactor device model 82 may be, at least partly, implemented by the cloud-based computing resource 40 as discussed with reference to FIG. 1, for instance using any of the above-mentioned cloud-computing technologies. Alternatively, the contactor device model 82 may be implemented by in-vehicle electronics, such as an internal vehicle controller or other microprocessor unit. The contactor device model 82 is configured to obtain the baseline signature 88 by employing data processing techniques.

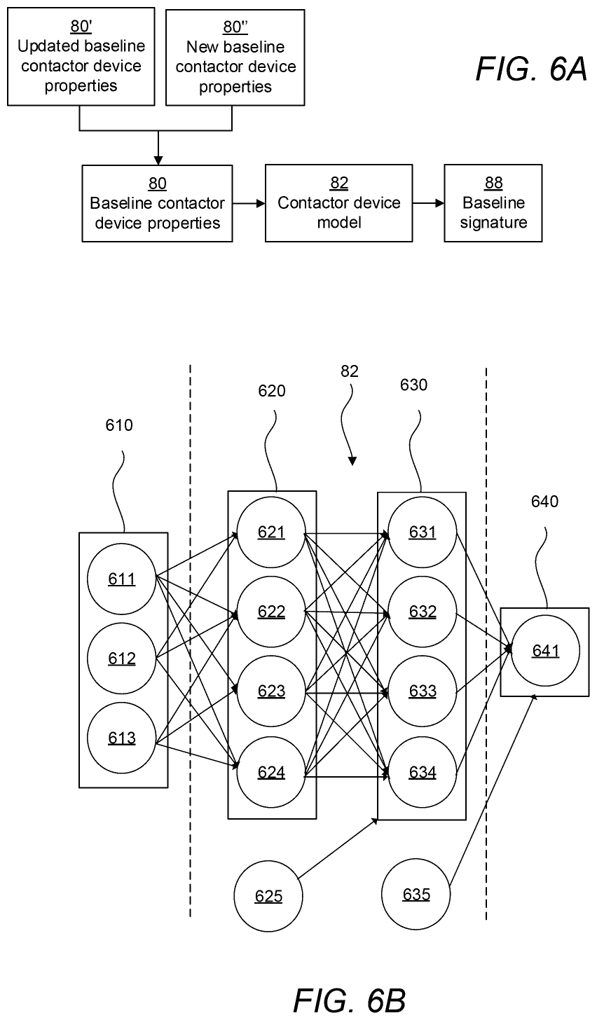

FIG. 6A-B show an exemplary contactor device model 82 and associated data used by the model 82 to output the baseline signature 88. The contactor device model 82 is in this example a neural network which is configured to employ machine learning approaches. The neural network is configured to continuously receive input data. The input data comprises baseline contactor device properties 80 being provided with updated baseline contactor device properties 80′ as well as new baseline contactor device properties 80″. The updated baseline contactor device properties 80′ correspond to new updates in already stored types of reference contactor device types. The new baseline contactor device properties 80″ correspond to contactor device types that have not yet been encountered by the neural network. The neural network is configured to perform a training procedure by processing the continuously received input data. The neural network is configured to output the baseline signature 88 taking into account the training procedure. A request for identification of a type of contactor may involve finding a suitable match of the response signature thereof with an output from the contactor device model 82. The trained neural network is capable of providing an intelligent identification of contactor device types based on previous identifications of contactor device types. During use, the neural network may be configured to mark correct and/or incorrect identifications to further take into account when performing additional identification procedures so as to learn from previous behavior, ultimately improving its accuracy. To this end, the neural network comprises self-learning features. Although being a neural network in this particular example, the contactor device model 82 may alternatively employ other supervised or unsupervised learning algorithms known in the art, such as binary, multi-class, or multi-label classification and/or clustering algorithms. For instance, algorithms such as logistic regression, support vector machines, kernel estimation, decision trees and/or neural networks may be utilized.

The contactor device model 82 being a neural network is shown according to one example in FIG. 6B. The neural network is exemplified as having an input layer 610, two hidden layers 620, 630, and an output layer 640. The input layer 610 comprises three nodes 611, 612, 613, the first hidden layer 620 comprises four nodes 621, 622, 623, 624, the second hidden layer 630 comprises four nodes 631, 632, 633, 634 and the output layer 640 comprises one node 641. Moreover, the neural network comprises two weight nodes 625, 635, each being associated with a respective hidden layer 620, 630. The skilled person appreciates that this is just an exemplary neural network that can be implemented as the contactor device model 82. Other networks may include any suitable number of input nodes, any suitable number of hidden layers and associated hidden nodes, any suitable number of output nodes, and any suitable number of weight nodes. The neural network may implement backpropagation for training purposes such that its performance of identifying contactor device types may be improved. The input nodes 611, 612, 613 may receive the input data as discussed above. The output node 641 may output the baseline signature 88 as a result of the processing of the input data by the hidden layers 620, 630 and associated weight nodes 625, 635.

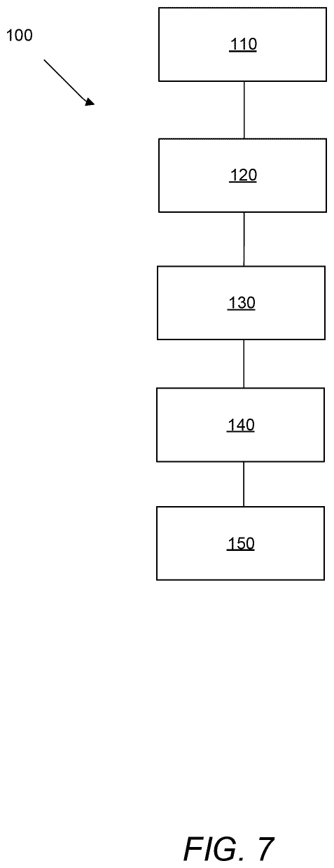

FIG. 7 is a flowchart of a method 100 for vehicle contactor device identification. The method 100 comprises providing 110, by processing circuitry of a computer system, a control signal to a contactor device control circuit comprising a contactor, the contactor device control circuit being configured to carry out a state switch in response to receiving said control signal. The method 100 comprises receiving 120, by the processing circuitry, a control signal response from the contactor device control circuit in response to said state switch being carried out. The method 100 comprises obtaining 130, by the processing circuitry, one or more contactor device properties based on the control signal response to the control signal. The method 100 comprises comparing 140, by the processing circuitry, the one or more contactor device properties to baseline contactor device properties, the baseline contactor device properties being indicative of one or more predefined contactor device types. The method 100 comprises, based on said comparison, identifying 150, by the processing circuitry, whether a type of said contactor corresponds to said one or more predefined contactor device types.

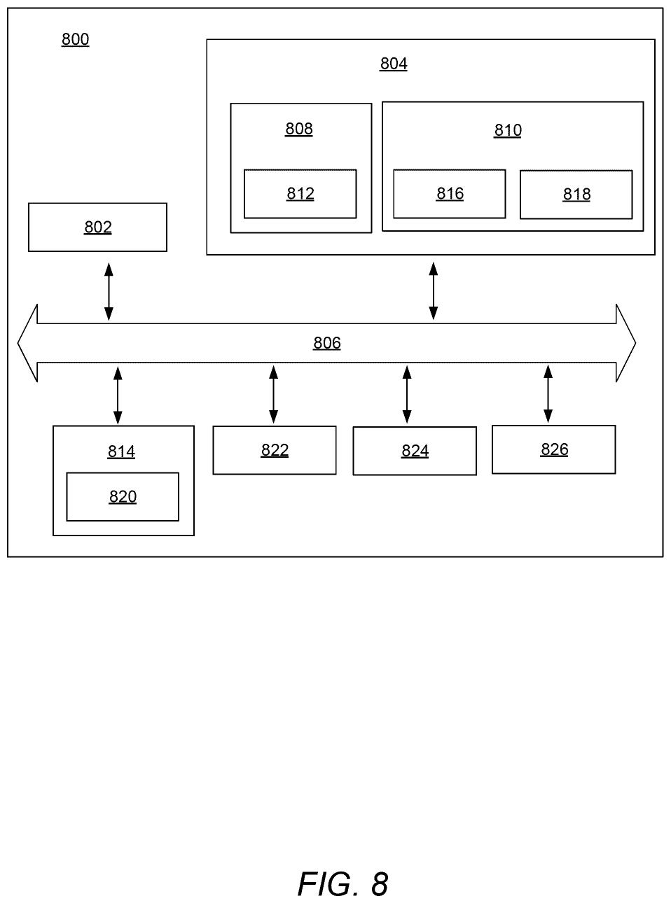

FIG. 8 is a schematic diagram of a computer system 800 for implementing examples disclosed herein. The computer system 800 is adapted to execute instructions from a computer-readable medium to perform these and/or any of the functions or processing described herein. The computer system 800 may be connected (e.g., networked) to other machines in a LAN, an intranet, an extranet, or the Internet. While only a single device is illustrated, the computer system 800 may include any collection of devices that individually or jointly execute a set (or multiple sets) of instructions to perform any one or more of the methodologies discussed herein. Accordingly, any reference in the disclosure and/or claims to a computer system, computing system, computer device, computing device, control system, control unit, electronic control unit (ECU), processor device, processing circuitry, etc., includes reference to one or more such devices to individually or jointly execute a set (or multiple sets) of instructions to perform any one or more of the methodologies discussed herein. For example, control system may include a single control unit or a plurality of control units connected or otherwise communicatively coupled to each other, such that any performed function may be distributed between the control units as desired. Further, such devices may communicate with each other or other devices by various system architectures, such as directly or via a Controller Area Network (CAN) bus, etc.

The computer system 800 may comprise at least one computing device or electronic device capable of including firmware, hardware, and/or executing software instructions to implement the functionality described herein. The computer system 800 may include processing circuitry 802 (e.g., processing circuitry including one or more processor devices or control units), a memory 804, and a system bus 806. The computer system 800 may include at least one computing device having the processing circuitry 802. The system bus 806 provides an interface for system components including, but not limited to, the memory 804 and the processing circuitry 802. The processing circuitry 802 may include any number of hardware components for conducting data or signal processing or for executing computer code stored in memory 804. The processing circuitry 802 may, for example, include a general-purpose processor, an application specific processor, a Digital Signal Processor (DSP), an Application Specific Integrated Circuit (ASIC), a Field Programmable Gate Array (FPGA), a circuit containing processing components, a group of distributed processing components, a group of distributed computers configured for processing, or other programmable logic device, discrete gate or transistor logic, discrete hardware components, or any combination thereof designed to perform the functions described herein. The processing circuitry 802 may further include computer executable code that controls operation of the programmable device.

The system bus 806 may be any of several types of bus structures that may further interconnect to a memory bus (with or without a memory controller), a peripheral bus, and/or a local bus using any of a variety of bus architectures. The memory 804 may be one or more devices for storing data and/or computer code for completing or facilitating methods described herein. The memory 804 may include database components, object code components, script components, or other types of information structure for supporting the various activities herein. Any distributed or local memory device may be utilized with the systems and methods of this description. The memory 804 may be communicably connected to the processing circuitry 802 (e.g., via a circuit or any other wired, wireless, or network connection) and may include computer code for executing one or more processes described herein. The memory 804 may include non-volatile memory 808 (e.g., read-only memory (ROM), erasable programmable read-only memory (EPROM), electrically erasable programmable read-only memory (EEPROM), etc.), and volatile memory 810 (e.g., random-access memory (RAM)), or any other medium which can be used to carry or store desired program code in the form of machine-executable instructions or data structures and which can be accessed by a computer or other machine with processing circuitry 802. A basic input/output system (BIOS) 812 may be stored in the non-volatile memory 808 and can include the basic routines that help to transfer information between elements within the computer system 800.

The computer system 800 may further include or be coupled to a non-transitory computer-readable storage medium such as the storage device 814, which may comprise, for example, an internal or external hard disk drive (HDD) (e.g., enhanced integrated drive electronics (EIDE) or serial advanced technology attachment (SATA)), HDD (e.g., EIDE or SATA) for storage, flash memory, or the like. The storage device 814 and other drives associated with computer-readable media and computer-usable media may provide non-volatile storage of data, data structures, computer-executable instructions, and the like.

Computer-code which is hard or soft coded may be provided in the form of one or more modules. The module(s) can be implemented as software and/or hard-coded in circuitry to implement the functionality described herein in whole or in part. The modules may be stored in the storage device 814 and/or in the volatile memory 810, which may include an operating system 816 and/or one or more program modules 818. All or a portion of the examples disclosed herein may be implemented as a computer program 820 stored on a transitory or non-transitory computer-usable or computer-readable storage medium (e.g., single medium or multiple media), such as the storage device 814, which includes complex programming instructions (e.g., complex computer-readable program code) to cause the processing circuitry 802 to carry out actions described herein. Thus, the computer-readable program code of the computer program 820 can comprise software instructions for implementing the functionality of the examples described herein when executed by the processing circuitry 802. In some examples, the storage device 814 may be a computer program product (e.g., readable storage medium) storing the computer program 820 thereon, where at least a portion of a computer program 820 may be loadable (e.g., into a processor) for implementing the functionality of the examples described herein when executed by the processing circuitry 802. The processing circuitry 802 may serve as a controller or control system for the computer system 800 that is to implement the functionality described herein.

The computer system 800 may include an input device interface 822 configured to receive input and selections to be communicated to the computer system 800 when executing instructions, such as from a keyboard, mouse, touch-sensitive surface, etc. Such input devices may be connected to the processing circuitry 802 through the input device interface 822 coupled to the system bus 806 but can be connected through other interfaces, such as a parallel port, an Institute of Electrical and Electronic Engineers (IEEE) 1394 serial port, a Universal Serial Bus (USB) port, an IR interface, and the like. The computer system 800 may include an output device interface 824 configured to forward output, such as to a display, a video display unit (e.g., a liquid crystal display (LCD) or a cathode ray tube (CRT)). The computer system 800 may include a communications interface 826 suitable for communicating with a network as appropriate or desired.

The operational actions described in any of the exemplary aspects herein are described to provide examples and discussion. The actions may be performed by hardware components, may be embodied in machine-executable instructions to cause a processor to perform the actions, or may be performed by a combination of hardware and software. Although a specific order of method actions may be shown or described, the order of the actions may differ. In addition, two or more actions may be performed concurrently or with partial concurrence.

Example 1: A computer system comprising processing circuitry configured to: provide a control signal to a contactor device control circuit comprising a contactor, the contactor device control circuit being configured to carry out a state switch in response to receiving said control signal; receive a control signal response from the contactor device control circuit in response to said state switch being carried out; obtain one or more contactor device properties based on the control signal response to the control signal; compare the one or more contactor device properties to baseline contactor device properties, the baseline contactor device properties being indicative of one or more predefined contactor device types; and based on said comparison, identify whether a type of said contactor corresponds to said one or more predefined contactor device types.

Example 2. The computer system of example 1, wherein the processing circuitry is further configured to obtain the one or more contactor device properties by time series analysis on time series data included in the control signal response.

Example 3: The computer system of example 2, wherein the processing circuitry is further configured to compare the one or more contactor device properties to the baseline contactor device properties by: creating a response signature of the one or more contactor device properties based on the time series analysis; creating a baseline signature of baseline time series data included in the baseline contactor device properties; and comparing said response signature to the baseline signature.

Example 4: The computer system of example 3, wherein the processing circuitry is further configured to create the baseline signature based on an output from a contactor device model being configured to process baseline contactor device properties of a plurality of said one or more predefined contactor device types.

Example 5: The computer system of example 3 or 4, wherein the processing circuitry is further configured to compare the response signature to the baseline signature by identifying deviations exceeding a predefined threshold value.

Example 6: The computer system of any of the examples 1-5, wherein the processing circuitry is further configured to provide an identification report in response to said identification of whether a type of said contactor corresponds to one or more predefined contactor device types being performed.

Example 7: The computer system of any of the examples 2-6, wherein the time series data pertain to a time-to-close duration of a closing operation of the contactor, said time-to-close duration being initiated upon said control signal being provided, said time-to-close duration ending upon completing the state switch, wherein the processing circuitry is further configured to determine the one or more contactor device properties as a function of a measured property of the control signal response in relation to a predefined property of the control signal during said closing operation.

Example 8: The computer system of any of the examples 2-6, wherein the time series data pertain to a time-to-open duration of an opening operation of the or a time-to-close duration of a closing operation of the contactor, said time-to-close or time-to-open duration being initiated upon said control signal being provided, said time-to-close or time-to-open duration ending upon completing the state switch, wherein the processing circuitry is further configured to pulse-width modulate the control signal 70.

Example 9: The computer system of any of the examples 1-8, wherein the one or more contactor device properties are electrical properties and/or physical properties of the contactor.

Example 10: The computer system of any of the examples 2-9, wherein the time series data is obtained by one or more sensor units.

Example 11: The computer system of any of the examples 1-10, wherein the contactor is a battery contactor.

Example 12: A vehicle comprising the computer system of any of examples 1-11.

Example 13: A computer-implemented method for contactor device identification, comprising: providing, by processing circuitry of a computer system, a control signal to a contactor device control circuit, the contactor device control circuit being configured to carry out a state switch in response to receiving said control signal; receiving, by the processing circuitry, a control signal response from the contactor device control circuit in response to said state switch being carried out; obtaining, by the processing circuitry, one or more contactor device properties based on the control signal response to the control signal; comparing, by the processing circuitry, the one or more contactor device properties to baseline contactor device properties, the baseline contactor device properties being indicative of one or more predefined contactor device types; and based on said comparison, identifying, by the processing circuitry, whether a type of said contactor device control circuit corresponds to said one or more predefined contactor device types.

Example 14: A computer program product comprising program code for performing, when executed by the processing circuitry, the method of example 13.

Example 15: A non-transitory computer-readable storage medium comprising instructions, which when executed by the processing circuitry, cause the processing circuitry to perform the method of example 13.

Example 16: The vehicle of example 12, wherein the contactor device control circuit is a circuit of a contactor, relay or switch arranged in an electrical machine of the vehicle.

Example 17: The vehicle of example 12 or 16, wherein the contactor device control circuit comprises a battery contactor, the battery contactor being a switching element capable of adjusting the electrical flow of control signals transferred through said contactor device control circuit.

Example 18: The vehicle of example 12 or 16-17, wherein the contactor device control circuit is connected to a stack of battery cells arranged in a battery of the vehicle, wherein the stack of battery cells is a series of individual battery cells being stacked together.

Example 19: The vehicle of example 12 or 16-18, further comprising a sensor unit arranged to provide measurements of the contactor device control circuit.

Example 20: The vehicle of example 12 or 16-19, further comprising a vehicle telematics unit and a cloud-based computing resource, wherein an identification report obtained in response to said identification of whether a type of said contactor corresponds to one or more predefined contactor device types is transferable between said vehicle telematics unit and said cloud-based computing resource.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. As used herein, the term “and/or” includes any and all combinations of one or more of the associated listed items. It will be further understood that the terms “comprises,” “comprising,” “includes,” and/or “including” when used herein specify the presence of stated features, integers, actions, steps, operations, elements, and/or components, but do not preclude the presence or addition of one or more other features, integers, actions, steps, operations, elements, components, and/or groups thereof.

It will be understood that, although the terms first, second, etc., may be used herein to describe various elements, these elements should not be limited by these terms. These terms are only used to distinguish one element from another. For example, a first element could be termed a second element, and, similarly, a second element could be termed a first element without departing from the scope of the present disclosure.

Relative terms such as “below” or “above” or “upper” or “lower” or “horizontal” or “vertical” may be used herein to describe a relationship of one element to another element as illustrated in the Figures. It will be understood that these terms and those discussed above are intended to encompass different orientations of the device in addition to the orientation depicted in the Figures. It will be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present.

Unless otherwise defined, all terms (including technical and scientific terms) used herein have the same meaning as commonly understood by one of ordinary skill in the art to which this disclosure belongs. It will be further understood that terms used herein should be interpreted as having a meaning consistent with their meaning in the context of this specification and the relevant art and will not be interpreted in an idealized or overly formal sense unless expressly so defined herein.

It is to be understood that the present disclosure is not limited to the aspects described above and illustrated in the drawings; rather, the skilled person will recognize that many changes and modifications may be made within the scope of the present disclosure and appended claims. In the drawings and specification, there have been disclosed aspects for purposes of illustration only and not for purposes of limitation, the scope of the disclosure being set forth in the following claims.

What is claimed is:

1. A computer system comprising processing circuitry configured to:
provide a control signal to a contactor device control circuit comprising a contactor, the contactor device control circuit being configured to carry out a state switch in response to receiving said control signal;
receive a control signal response from the contactor device control circuit in response to said state switch;
obtain one or more contactor device properties based on the control signal response to the control signal;
compare the one or more contactor device properties to baseline contactor device properties, the baseline contactor device properties being indicative of one or more predefined contactor device types; and
based on said comparison, identify whether a type of said contactor corresponds to said one or more predefined contactor device types.

2. The computer system of claim 1, wherein the processing circuitry is further configured to obtain the one or more contactor device properties by time series analysis on time series data included in the control signal response.

3. The computer system of claim 2, wherein the processing circuitry is further configured to compare the one or more contactor device properties to the baseline contactor device properties by:
creating a response signature of the one or more contactor device properties based on the time series analysis;
creating a baseline signature of baseline time series data included in the baseline contactor device properties; and
comparing said response signature to the baseline signature.

4. The computer system of claim 3, wherein the processing circuitry is further configured to create the baseline signature based on an output from a contactor device model being configured to process baseline contactor device properties of a plurality of said one or more predefined contactor device types.

5. The computer system of claim 3, wherein the processing circuitry is further configured to compare the response signature to the baseline signature by identifying deviations exceeding a predefined threshold value.

6. The computer system of claim 1, wherein the processing circuitry is further configured to provide an identification report in response to said identification of whether a type of said contactor corresponds to one or more predefined contactor device types being performed.

7. The computer system of claim 2, wherein the time series data pertain to a time-to-close duration of a closing operation of the contactor, said time-to-close duration being initiated upon said control signal input being provided and said time-to-close duration ending upon completing the state switch,
wherein the processing circuitry is further configured to determine the one or more contactor device properties as a function of a measured property of the control signal response in relation to a predefined property of the control signal during said closing operation.

8. The computer system of claim 2, wherein the time series data pertain to a time-to-open duration of an opening operation of the contactor or a time-to-close duration of a closing operation of the contactor, said time-to-close or time-to-open duration being initiated upon said control signal being provided, said time-to-close or time-to-open duration ending upon completing the state switch,
wherein the processing circuitry is further configured to pulse-width modulate the control signal.

9. The computer system of claim 1, wherein the one or more contactor device properties are electrical properties and/or physical properties of the contactor.

10. The computer system of claim 2, wherein the time series data is obtained by one or more sensor units.

11. The computer system of claim 1, wherein the contactor is a battery contactor.

12. A vehicle comprising the computer system of claim 1.

13. The vehicle of claim 12, wherein the contactor device control circuit is a circuit of a contactor, relay or switch arranged in an electrical machine of the vehicle.

14. The vehicle of claim 12, wherein the contactor device control circuit comprises a battery contactor, the battery contactor being a switching element capable of adjusting the electrical flow of control signals transferred through said contactor device control circuit.

15. The vehicle of claim 12, wherein the contactor device control circuit is connected to a stack of battery cells arranged in a battery of the vehicle, wherein the stack of battery cells is a series of individual battery cells being stacked together.

16. The vehicle of claim 12, further comprising a sensor unit arranged to provide measurements of the contactor device control circuit.

17. The vehicle of claim 12, further comprising a vehicle telematics unit and a cloud-based computing resource, wherein an identification report obtained in response to said identification of whether a type of said contactor corresponds to one or more predefined contactor device types is transferable between said vehicle telematics unit and said cloud-based computing resource.

18. A computer-implemented method for contactor device identification, comprising:
providing, by processing circuitry of a computer system, a control signal to a contactor device control circuit comprising a contactor, the contactor device control circuit being configured to carry out a state switch in response to receiving said control signal;
receiving, by the processing circuitry, a control signal response from the contactor device control circuit in response to said state switch;
obtaining, by the processing circuitry, one or more contactor device properties based on the control signal response to the control signal;
comparing, by the processing circuitry, the one or more contactor device properties to baseline contactor device properties, the baseline contactor device properties being indicative of one or more predefined contactor device types; and
based on said comparison, identifying, by the processing circuitry, whether a type of said contactor corresponds to said one or more predefined contactor device types.

19. A computer program product comprising program code for performing, when executed by the processing circuitry, the method of claim 18.

20. A non-transitory computer-readable storage medium comprising instructions, which when executed by the processing circuitry, cause the processing circuitry to perform the method of claim 18.
